(19) United States
(12) Patent Application Publication
(10) Pub. No.: US 2017/0276748 A1
(43) Pub. Date: Sep. 28, 2017

(54) FORCE REDUCED MAGNETIC SHIM DRAWER

(71) Applicant: GENERAL ELECTRIC COMPANY, Schenectady, NY (US)

(72) Inventors: Paul St. Mark Shadforth THOMPSON, Stephentown, NY (US); Mark Ernest VERMILYEA, Niskayuna, NY (US); Minfeng XU, Niskayuna, NY (US)

(73) Assignee: GENERAL ELECTRIC COMPANY, Schenectady, NY (US)

(21) Appl. No.: 15/081,013

(22) Filed: Mar. 25, 2016

(51) Int. Cl. G01R 33/3875; G01R 33/385

(52) U.S. Cl. CPC G01R 33/3875; G01R 33/3856

(57) ABSTRACT

An MRI scanner can include a magnet assembly forming a central magnetic field area, and a slot for receiving a shim drawer formed within the central magnetic field area. There can be included a shim drawer received within the slot. The shim drawer can be configured to carry one or more metal shim and the shim drawer can be formed of conductive material.

### FIELD

The disclosure relates to magnetic resonance imaging (MRI) systems in general and in particular to a shim drawer for an MRI system.

### BACKGROUND

MRI scanners are characterized by strong or large magnetic fields in a small imaging bore or volume with a very high degree of uniformity or homogeneity. Prior to be placed into use, an MRI scannner can be tuned to exhibit a specified level of homogeneity. After manufacturing the magnet with the best achievable tolerances, the inhomogeneity can be up to orders of magnitude above the desired level, and a magnetic field shimming system is used to reduce the inhomogeneity level.

Inhomogeneities in the primary magnetic field are a result of manufacturing tolerances for the magnet, and equipment and site conditions. Magnetic field inhomogeneities distort the position information in the imaging volume and degrade the image quality. The imaging volume must have a low magnetic field inhomogeneity for high quality imaging. Shimming is a known technique for reducing the inhomogeneity of the primary magnetic field. The primary magnetic field can be pictured as a large constant field with small inhomogeneous field components superimposed on the constant field. If the negative of the inhomogeneous components of the field can be generated, the net field will be made uniform and the magnet is then said to be shimmed.

In practice, shim systems utilize extra coils, typically called correction or shimming coils, small pieces of iron, typically called passive shims, or some combination of the two to correct or improve the magnetic field homogeneity while allowing reasonable manufacturing tolerances. Current flow provided through the shimming coils produce magnetic fields to cancel and/or minimize the magnetic field inhomogeneities in the imaging volume.

Correction coils are capable of creating different field shapes which can be superimposed on an inhomogeneous main magnetic field to perturb the main magnetic field in a manner which increases the overall field uniformity. These coils can add significantly to the cost and complexity of the magnet.

In addition to or in place of correction methods involving correction coils, passive shimming can be used to correct large deviations in magnetic fields that cannot be corrected by the available correction coils alone. The passive shimming is accomplished by placing a piece of iron in an appropriate place external to the magnet. The desired level of field uniformity can then be achieved by the correction coils.

Passive shimming is accomplished using shims comprised of ferromagnetic materials such as carbon steel. A magnetic field arising from an induced magnetic dipole of the shim is used to cancel out the inhomogeneous field components. The number, mass, and position of the shims are determined by known shimming techniques. In one commercial implementation, the shims are contained in a shim assembly located near a gradient coil structure that generates the x, y, and z gradient magnetic fields used for MRI.

Passive shimming is a method of magnetic field correction involving the use of ferromagnetic materials, typically iron or steel, placed in a regular pattern at specific locations along the inner bore of the magnet. In one commercial implementation a plurality of shimming trays are arranged symmetrically around the circumference of the magnet. Each tray slides along an axis parallel with a central axis of an MM scanner and contains pockets into which a desired number of ferromagnetic shim elements can be placed. The specific trays, slots, number, and size of shim elements to be inserted are determined by specialized shimming software used during the magnetic field mapping process. Several iterations of this process may be required until the desired level of homogeneity is reached.

### BRIEF DESCRIPTION

An MRI scanner can include a magnet assembly forming a central magnetic field area, and a slot for receiving a shim drawer formed within the central magnetic field area. There can be included a shim drawer received within the slot. The shim drawer can be configured to carry one or more metal shim and the shim drawer can be formed of conductive material.

### DRAWINGS

FIG. 1 is a partial perspective of an MRI scanner in one embodiment, having conductive, e.g., aluminum shim drawers;

FIG. 2 is a side cross sectional view of an MRI scanner in one embodiment;

FIG. 3 is front cross sectional view of an MRI scanner in one embodiment;

FIG. 4 is a perspective view of a passive shimming shim assembly in one embodiment having an conductive, e.g., aluminum shim drawer that can induce eddy currents on drawer entry;

FIG. 5 is a cross sectional view of a shim drawer in one embodiment;

FIG. 6 is a cross section view of a shim in one embodiment;

FIG. 7 is a perspective view of an MRI scanner in one embodiment having a plurality of electrically connected shim drawers;

FIG. 8 is perspective view of an MRI scanner in one embodiment having a plurality of electrically connected shim drawers;

FIG. 9 is a cross sectional view of a shim drawer in one embodiment;

FIG. 10 is a perspective view of a conductive bore in one embodiment wherein the conductive bore is configured to support shim drawers; and

FIG. 11 is a cross sectional view of a conductive bore in one embodiment.

### DETAILED DESCRIPTION

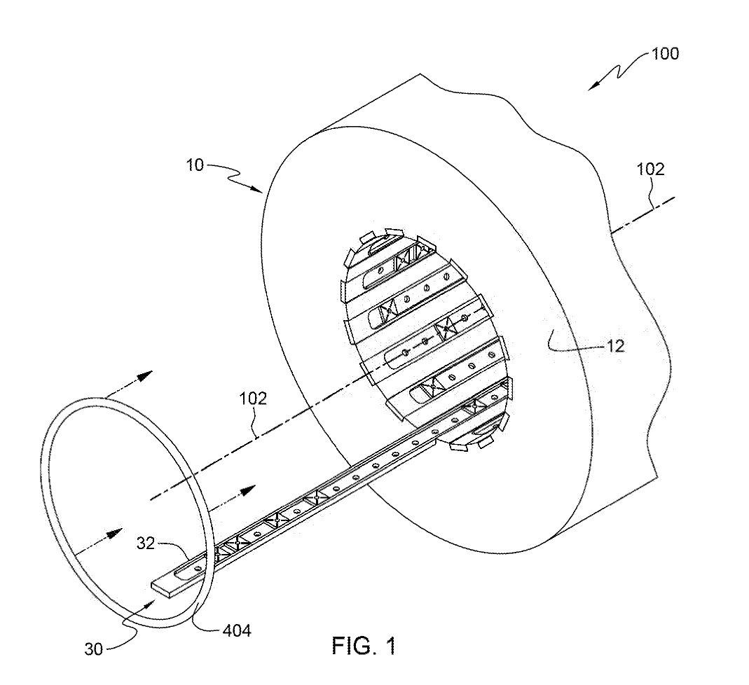

Referring to FIG. 1 showing an MRI scanner 100 in perspective view, an MRI scanner 100 can include an MR magnet assembly 10 disposed about a central axis 102 and a plurality of shim drawer assemblies 30. A shim drawer assembly 30 of an MRI scanner 100 according to embodiments set forth herein can be configured to damp dynamic motion of a shim drawer assembly 30 when inserting into a magnetic resource (MR) magnet assembly 10.

Embodiments herein recognize that MRI scanner 10 can impart a strong pushing or pulling force on a shim drawer assembly 30 when a shim drawer assembly 30 is installed into or removed from an MRI scanner 100 requiring special hardware that adds cost and time to the shimming process or posing a risk to an operator or machine equipment performing the installing or removing. In one embodiment, a shim drawer 32 of shim drawer assembly 30 can be configured to generate eddy currents to damp forces imparted on shim assembly 10 when shim drawer assembly 30 is installed.

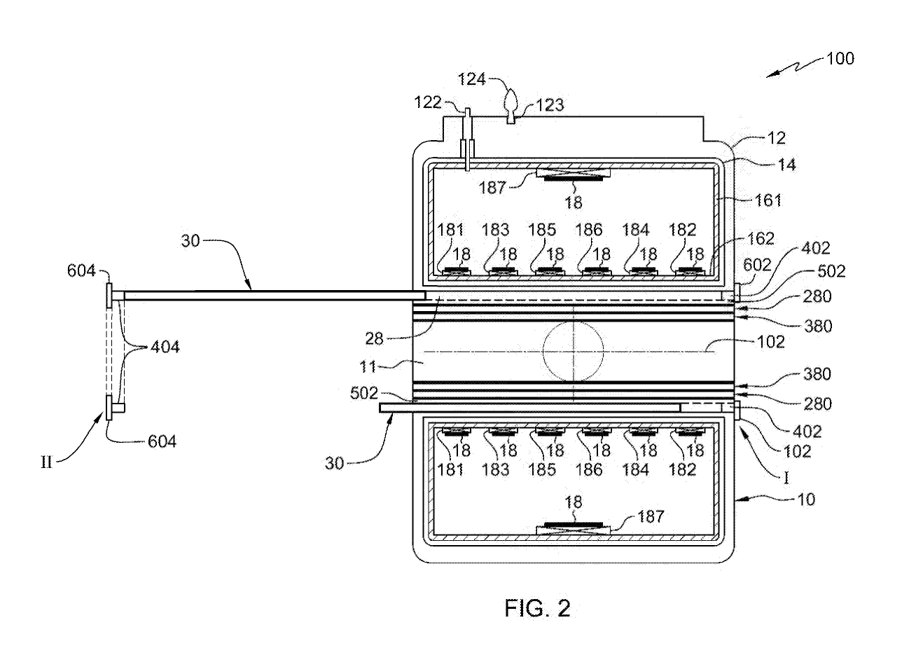

A side cross sectional view of an Mill scanner 100 having central axis 102 is shown in FIG. 2. As an example, the superconducting magnet assembly 10 can include a donut-shaped vacuum vessel 12 forming a central magnetic field area 11 delimited by magnet assembly 10, a donut-shaped thermal shield 14 concentrically within the vacuum vessel 12, and a cooling apparatus concentrically within the thermal shield 14. In this embodiment, a donut-shaped cryogen vessel 161 arranged concentrically within the thermal shield 14 is used as the cooling apparatus. The cooling apparatus can be used for cooling and maintaining the superconducting magnet assembly 10 to an extremely low temperature.

In the illustrated embodiment of FIG. 2, the superconducting magnet assembly 10 includes a number N (N is an integer) of superconducting coils. The number N of superconducting coils 18 include multiple main superconducting coils 181, 182, 183, 184, 185, 186 and a shielding/bucking superconducting coil 187. The main superconducting coils 181-186 are wounded on or attached to a center inner surface 162 of the cryogen vessel 161. The shielding/bucking superconducting coil 187 can be wounded on or attached to a periphery inner surface 164 of the cryogen vessel 161. Namely the center inner surface 162 and the periphery inner surface 164 act as a coil support structure to support the number N of superconducting coils. The superconducting coils 181-187 as shown in FIG. 2 are cooled by the cryogen, for example liquid helium, contained in the cryogen vessel. In other embodiments, the number N of superconducting coils 181-187 may be installed on other kinds of coil support structures such as metal formers, metal bars, fiberglass reinforced plastic (FRP) former, or FRP bars, which are not described here.

In the illustrated embodiment of FIG. 2, the vacuum vessel 12 may include a refrigerator 122 communicating with the thermal shield 14 and the cryogen vessel 161 to refrigerate the number N of superconducting coils 18. For example, the cryogen vessel 161 is refrigerated down to about 4.2 kelvins (K). The space between the cryogen vessel 161 and the thermal shield 14 is refrigerated to an appropriate temperature. The vacuum vessel 12 can also include a service port 123 providing communicating ports having multiple power leads 124 used to electrically couple external power to the superconducting coils 18 and other electrical parts. In other embodiments, the cryogen vessel 161 used for cooling of the number N of superconducting coils 181-187 can be removed, or other kinds of direct-conduction refrigerating means may be used as the cooling apparatus to refrigerate the number N of superconducting coils 181-187 to an operating cryogenic temperature.

In some specific embodiments, the superconducting magnet assembly 10 can be configured as a low temperature superconducting magnet assembly by fabricating the superconducting coils with low temperature superconductors. In another embodiment, the superconducting magnet assembly 10 also can be other types of superconducting magnet assembles. The superconducting magnet assembly 10 can be used in many suitable fields, such as used in a magnetic resonance imaging (MM) system and so on.

As an example, in the illustrated embodiment of FIG. 2, the main superconducting coils 181-186 includes six superconducting coils which have two large superconducting coils 181 and 182, two medium superconducting coils 183 and 184, and two small superconducting coils 185 and 186. The large superconducting coils 181 and 182 are arranged at the two axially outer sides of the center inner surface 162, the small superconducting coils 185 and 186 are arranged at the center of the center inner surface 162, and the medium superconducting coils 183 and 184 are arranged axially between the other two superconducting coils as shown in FIG. 2. In some embodiments, the width of the small superconducting coils 185 and 186 are the smallest, the width of the large superconducting coils 181 and 182 are the largest, and the width of the medium superconducting coils 183 and 184 are between the other two superconducting coils. In other embodiments, the number, the width, and the location arrangement of those main superconducting coils 181-186 can be adjusted according to different design requirements.

In the illustrated embodiment of FIG. 2, the number of the bucking superconducting coil 187 is only one. In other embodiments, the number of the bucking superconducting coils 187 may be two or more. The bucking superconducting coil 187 is configured to generate a magnetic shield to prevent the magnet field created by the main superconducting coils 181-186 from going beyond a designated footprint area.

In other embodiments, the magnetic shield also can be generated by other types of configurations without using the bucking superconducting coil 187. For example, the vacuum vessel 12 can be designed as a magnetic shield. In non-limited embodiments, the vacuum vessel 12 may employ iron shields (iron yokes) for shielding the magnetic field area 11 for example. In other embodiments, the magnetic shield also can be generated by both bucking superconducting coils 187 and the iron shields. In a further aspect each of the superconducting coils 181-186; as well as bucking coil 187, can include an associated heater 18 for providing heat to a respective superconducting coil 181-186 for the purpose of spreading heat during a quench.

During a magnet ramp-up process, an external power source (not shown) provides power to the number N of superconducting coils 181-187 through power leads 124. Once the number N of superconducting coils 181-187 are energized to pre-determined current and magnetic field, a main superconducting switch can be closed to establish a closed superconducting loop with the number N of superconducting coils 18. Therefore, a magnetic field is generated in the magnet field area 11 by the main superconducting coils 181-186, and a magnetic shield is also generated by the bucking superconducting coil 187. It is understood that other conventional additional circuit elements may be further applied in a quench protection apparatus which are not described and shown here for simplicity of illustration.

In another aspect MRI scanner 100 can include a plurality of shim drawer slots 28. Each shim drawer slot 28 can be configured to receive a shim drawer assembly 30. In another aspect MRI scanner 100 as shown in FIG. 2 can include gradient coil assembly 280 having one or more gradient coil. In another aspect MRI scanner 100 as shown in FIG. 2 can include an RF coil assembly 380 having one or more RF coil. MRI scanner 100 as shown in FIG. 1 is illustrated in an intermediary stage of manufacture without assembly 280 or assembly 380.

As shown in the embodiment FIG. 2, shim drawer slots 28 can be formed concentric and inwardly relative to magnet assembly 10 and concentric and outwardly relative to gradient coil assembly 280. Gradient coil assembly 280 can be formed concentric and inwardly relative to shim drawer slots 28 and concentric and outwardly relative to RF coil assembly 380.

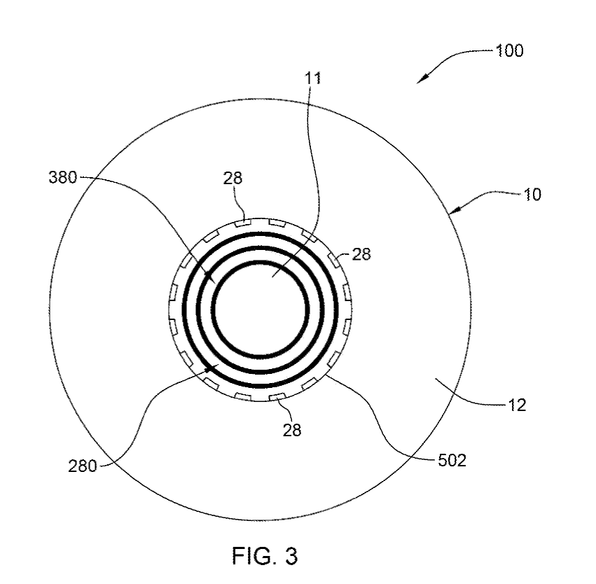

FIG. 3 is a front cross sectional of MRI scanner 100. As shown in FIGS. 2 and 3, shim drawer slots 28 can be formed concentric and inwardly relative to magnet assembly 10 and concentric and outwardly relative to gradient coil assembly 280. Coil assembly 280 can be formed concentric and inwardly relative to shim drawer slots 28 and concentric and outwardly relative to RF coil assembly 380. In the embodiment of FIG. 1-3, MRI scanner 100 can include sixteen slots 28 for receiving sixteen shim drawer assemblies 30, there being one shim drawer assembly per slot. MRI scanner 100 can be configured to include any number of slots and corresponding shim drawer assemblies, e.g., 4, 16, 32, 54, 64 etc. Referring to FIGS. 1-3, a plurality of shim drawer assemblies 30 can be loaded into respective slots around the periphery of gradient coil assembly 280 intermediate the gradient coil assembly 280 and magnet assembly 10. A representative shim drawer assembly 30 can include a shim drawer 32 and a plurality of ferromagnetic (e.g., iron) shims 34.

According to a passive shimming procedure, a Nuclear Magnetic Resonance (NMR) sensor (not shown) can be used to measure a magnetic field generated by magnet assembly 10. Data generated by the NMR sensor can be analyzed to output a report designating location of shims 34 that would correct for non-uniformities in a magnetic field. An operator can then remove the appropriate shim drawer assemblies 30 from MR magnet assembly 10, locate shims as required by the report, then reinstall the appropriate shim assemblies. The NMR sensor can be used to measure the magnetic field again and a further report can be generated with locations of shims to further reduce non-uniformities in the magnetic field. Typically one to a number of iterations can be performed so that non-uniformities are reduced to within an acceptable degree of non-uniformity. According to a method set forth herein an MR magnet assembly 10 can be magnetically shimmed using shims 34, e.g., provided by iron pieces mechanically fixed to a shim drawer 32 of a shim drawer assembly 30.

Embodiments herein recognize that shim drawers 32 are typically made of non-ferromagnetic insulator material and are often made using such materials as fiber reinforced plastic (FRP) materials or fiberglass reinforced plastic (GRP) material. Embodiments herein recognize that when installing or removing a non-ferromagnetic insulator shim drawer, high forces can be imparted by magnet assembly 10 on the ferromagnetic shims 34 as they move through a central magnetic area 12 formed by and delimited by magnet assembly 10 and typically require extensive mechanical structures/machines to counteract these forces and allow gradual insertion of the shim drawers 32. Embodiments herein recognize that the use a conductive shim drawer 32 will add significant safety benefits to the operator. Since a conductive structure moving through a magnetic field will induce an eddy current that will partially counteract the forces and slow any rapid movement, the operator is protected from harm. The solution provided can be regarded as an eddy current brake system.

Embodiments herein recognize that plastic based, e.g., GRP or FRP shim drawers that are heavily loaded with magnetic material (i.e. shims) can act simply as carriers for the magnetic material. The magnetic material will tend to be pulled into a magnetic field proportional to inverse square of the distance the material is away from the field. Also, citing Lenz's law, an induced current in a closed conducting loop will appear in such a direction that it opposes the change that produced it.

F=iL×B (Eq. 1)

Where F is the force that opposes an attractive force (e.g. of one or more shim 34), i is the induced eddy current, L is the effective length of the conductive loop (e.g. defined by the part of the conductive shim drawer 32 into which currents are induced) and B is the background magnetic field (e.g. through which shim drawer 32 is being moved). In accordance with Lenz's law, the direction of eddy currents induced in a conductor by a changing magnetic field will be such that a magnetic field produced by the induced eddy current will oppose the original magnetic field. Accordingly, it will be seen that providing a shim drawer 32 to include a conductive material will provide a force damping mechanism.

A shim drawer assembly 30 having a shim drawer 32 can provide damping of dynamic motion of the shim drawer 32 when inserting heavily loaded magnetic shim drawers into an MRI scanner 100. As a conductive shim drawer 32 carrying metal shims 34 is inserted into a MRI scanner 100 and is moved through the magnetic field, eddy currents can be induced in the conductive material of the shim drawer 32 to generate an opposing magnetic field that dampens rapid movement of the shim drawer 32. The resulting reduction in acceleration can reduce the dynamic forces required to insert the shim drawer 32 and also reduce potential operator injury. As an additional benefit a conductive shim drawer 32 can reduce magnet/gradient interactions that will tend to enhance imaging performance.

As set forth herein, shim drawer 32 can be formed of conductive material. In another aspect, shim drawer 32 can be formed of non-ferromagnetic conductive material. Suitable material for shim drawer 32 includes e.g. aluminum (Al) or copper (Cu). A shim drawer 32 in one embodiment can be of multi-part construction. A shim drawer 32 in one embodiment can be of unitary (single piece) construction.

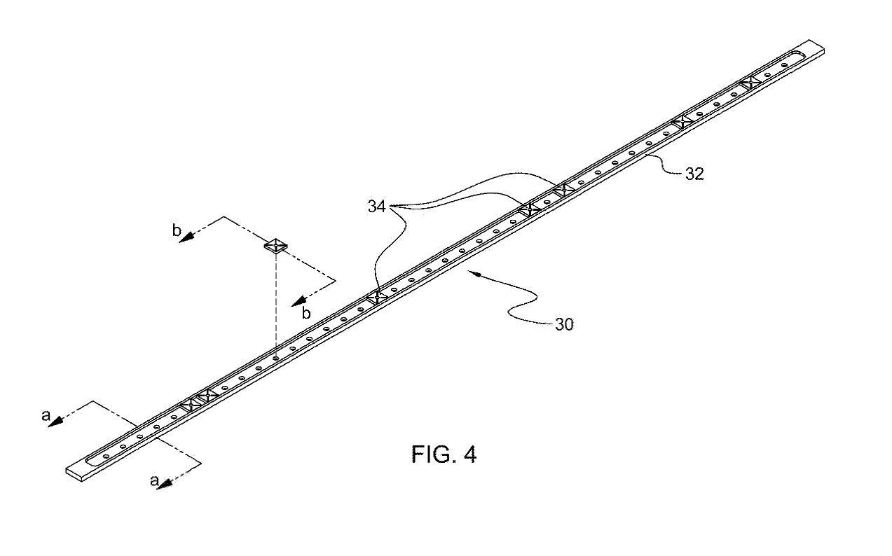

FIG. 4 is a perspective view of a shim drawer assembly having a shim drawer 32 and or more shims 34. The locations of shims 34 can be adjusted by an operator including by installing or removing or more shims from shim drawer 32 or changing locations of one or more shim 34. In one embodiment, each of shim drawer 32 and shims 34 can be conductive. In one embodiment, shim drawer 32 can be formed of a non-ferromagnetic conductive material and shims 34 can be formed of ferromagnetic conductive material. In one embodiment, shim drawer 32 can be formed of a non-ferromagnetic conductive metal and shims 34 can be formed of ferromagnetic conductive metal.

While advantages can be yielded by providing each of shim drawer 32 and shims 34 to be formed conductive material and in one embodiment metal material, embodiments herein recognize that interfaces between bodies of conductive material can negatively impact imaging. Embodiments herein recognize that interfaces between conductive material bodies (e.g., metal to metal between contact different bodies) can yield white pixel noise.

In one embodiment one or more of shim drawer 32 and shims 34 can include an insulator coating that reduces or prevents contact between conductive material of drawer 32 and conductive material of shims 34.

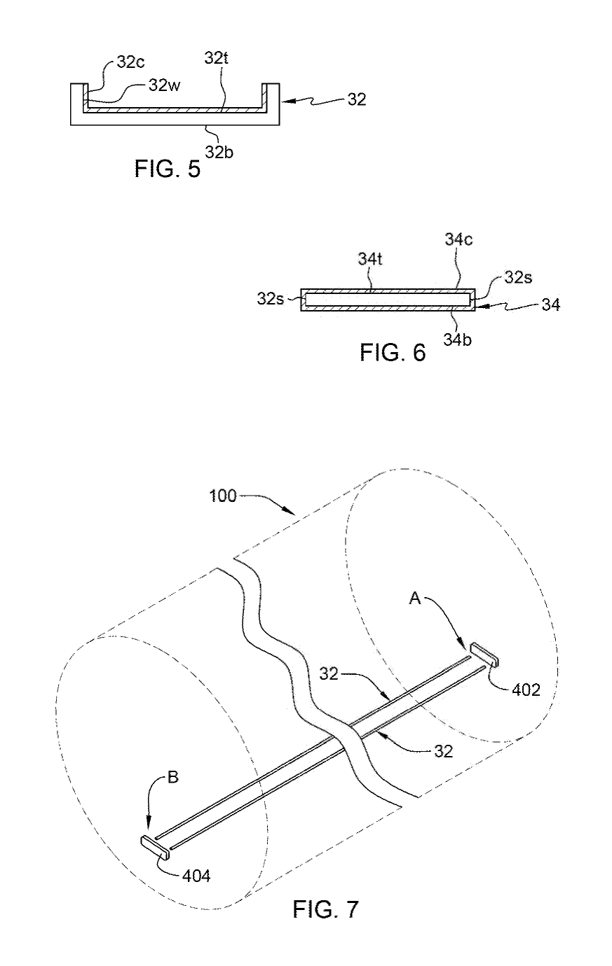

An insulator coating herein can include e.g., a material formed by an anodizing process in which material forming shim drawer 32 is anodized. An insulator coating of drawer 32 and/or shims 34 can be, e.g., formed by anodizing the material of shim drawer 32 and/or shims 34. An insulator coating of shim drawer 32 and/or shims 34 can in addition or alternatively be formed by a process including spraying on, painting on, or applying by dipping. A cross section of shim drawer 32 taken along line a-a of FIG. 4 is shown in FIG. 5. Shim drawer 32 can include insulator coating 32c in one embodiment, e.g., formed by anodizing the material of shim drawer 32. As shown in the embodiment of FIG. 5, insulator coating 22c can cover a top surface 32t of shim drawer 32 as well as interior walls 32w of shim drawer 32. A cross section of shim 34 taken along line b-b of FIG. 4 is shown in FIG. 6. Shim 34 can include an insulator coating 34c in one embodiment, e.g., formed by anodizing the material of shim 34. Coating 34c as shown in the embodiment of FIG. 6 can cover a bottom surface 34b of a shim 34, a top surface 34t of shim 34 and each side surface 34s of shim 34.

Various advantages can be provided by forming a shim drawer 32 to include conductive material. Conductive material, e.g., aluminum offers higher stiffness and strength relative to an alternative material such as fiber reinforced plastic (FRP) and can be utilized to support large shim loads. Additionally, conductive material of shim drawer 32 will tend to shield the superconducting coils 281-287 of magnet assembly 10 from gradient fields during imaging. In one embodiment, a magnetic field generated by gradient coil assembly 280 can induce eddy currents in one or more shim drawer 32. Eddy currents in one or more shim drawer 32 can generate a magnetic field that opposes the magnetic field generated by the gradient coil assembly 280 to shield magnetic flux lines of the magnetic field generated by the gradient coil assembly from reaching the superconducting coils 181-187 where such magnetic flux lines could negatively impact operation of magnet assembly 10. Accordingly, system performance during imaging can be improved by the presence of one or more shim drawers 32.

In one aspect, MRI scanner 100 can be configured to increase a magnetic field shielding effect provided by one or more shim drawer 32. Referring to FIG. 7 MRI scanner 100 can be configured so that two or more of shim drawers 32 are electrically connected. In one embodiment, as shown in FIG. 7 MRI scanner 100 can be configured to include conductive member 402 that electrically connects a first shim drawer 32 and a second shim drawer 32 as shown in FIG. 7. Referring to FIG. 7 MRI scanner 100 can be configured so that two or more of shim drawers 32 are electrically connected at first and second locations to provide a closed loop conductive current path that allows current to flow in a closed loop that includes first and second shim drawers. In one embodiment, as shown in FIG. 7 MRI scanner 100 can be configured to include conductive member 402 that electrically connects a first shim drawer 32 and a second shim drawer 32 at a first locations “A” and a conductive member 404 that electrically connects first shim drawer 32 and second shim drawer 32 at a second locations “B” to provide a closed loop conductive path defined by first shim drawer 32 conductive member 402 second shim drawer 32 and conductive member 404. Conductive members 402 and 404 can be of multiple part construction or unitary construction. With first and second shim drawers 32 defining a closed loop conductive path current flow attributable to eddy currents induced in the shim drawers by gradient coil assembly 280 can be expected to be increased. Accordingly, a resulting magnetic field produced by the induced eddy currents to oppose the magnetic field generated by the gradient coil assembly can be expected to increase, thereby further shielding magnetic flux lines generated by gradient coil assembly 280 from reaching magnet assembly 10.

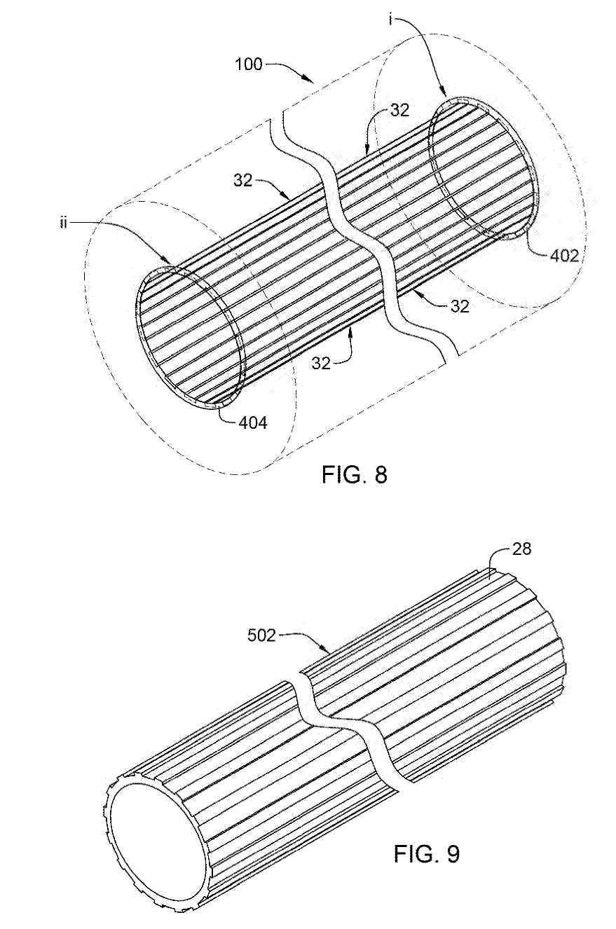

In one embodiment, more than two shim drawers, e.g. three, four, all shim drawers 32 of MRI scanner 100 can be electrically connected to increase current flow through shim drawers 32. In one embodiment, each shim drawer 32 of MRI scanner 100 is electrically connected, e.g., 8 shim drawers can be electrically connected where scanner 100 includes 16 shim drawers, 16 shim drawers can be electrically connected where scanner 100 includes 8 shim drawers, 32 shim drawers can be electrically connected where scanner 100 includes 32 shim drawers, 54 shim drawers can be electrically connected where scanner 100 includes 54 shim drawers. In the embodiment of FIG. 8 conductive member 402 having a ring configuration can electrically connect each shim drawer 32 of MRI scanner 100 at first locations “i” and further so that conductive member 404 having a ring configuration can electrically connect each shim drawer 32 of MRI scanner 100 at second locations “ii” spaced apart from the first locations to provide closed loop conductive paths for increased current flow through shim drawers 32. Conductive members 402 can be of multi-part or of unitary construction. Suitable material for conductive members include e.g., aluminum (Al) or copper (Cu).

MRI scanner 100 can be configured so that conductive members 402 and 404 for electrically connecting shim drawers 32 can be supported within MRI scanner 100. Referring to FIG. 8 conductive member 402 can be fixedly mounted within MM scanner 100 so that shim drawers 32 that are installed in scanner 100 contact member 402 when fully installed.

Referring to FIG. 8 MRI scanner 100 can be configured so that conductive member 404 is removeably installed in MRI scanner 100. MRI scanner 100 can be configured so that when shim drawers 32 are fully installed to contact conductive member 402 at first locations “ii” conductive member 404 can be installed to contact shim drawers 32 at second locations “ii” can be secured in a fixed position so that a conductive path is maintained between shim drawers 32 of scanner 100. An embodiment of conductive member 402 is a fixed position as shown in FIG. 2. An embodiment of a conductive member 404 configured to be removeably replaceable is show in FIGS. 1 and 2.

For increased shielding of a magnetic field generated by gradient assembly 280 MRI scanner 100 can include a conductive shielding bore disposed about a gradient coil assembly 280. Referring to FIGS. 2 and 3 bore 502 can be disposed concentric and outwardly relative to gradient coil assembly 280, and can be configured to include drawer supporting slots 28 that support shim drawers 30. Bore 502 can include a cylindrical configuration as shown in FIG. 9. In one embodiment, bore 502 can be configured to be formed of conductive material. Suitable material for bore 502 includes e.g. aluminum (Al), copper (Cu), gold (Au) or silver (Ag). A magnetic field generated by gradient coil assembly 280 can be expected to induce eddy currents in bore 502 which eddy currents can generate an opposing magnetic field to oppose the magnetic field generated by gradient coil assembly 280.

Embodiments herein recognize that conductive material to conductive material, (e.g., metal to metal) contact between bore 502 and shim drawers 32 can yield white pixel noise thus negatively impacting imaging performance. In one aspect one or more of shim drawer 32 and bore 502 can include an insulator material to reduce or prevent conductive material to conductive material contact between bore 502 and shim drawer 32. An insulator coating herein can be formed by an anodizing process. An insulator coating of drawer 32 and/or bore 502 can be, e.g., formed by anodizing a material of shim drawer 32 and/or bore 502 and/or can be sprayed on, painted on or formed by dipping.

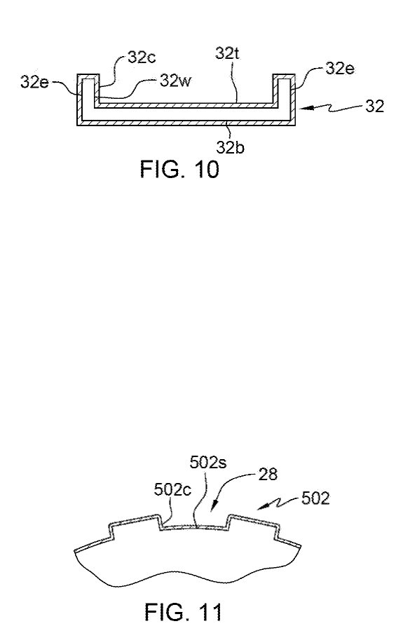

A cross section of shim drawer 32 taken along line a-a of FIG. 4 in one embodiment is shown in FIG. 10. It was described earlier that a top surface 32t of shim drawer 32 for supporting a shim 34 as well an internal walls 32w can be coated with insulator material 32c. In another aspect as set forth in FIG. 10 exterior side surfaces 32e as well as bottom surface 32b of shim drawer 32 can include an insulator coating 32c. Referring to FIG. 11 the cross sectional view of bore 502 having slots 28 for supporting shim drawers 32 an exterior surface 502s of bore 502 defining slots 28 can include a coating 502c of an insulator material.

In one embodiment, for increased eddy current inducement and an increased magnetic field to oppose a magnetic field generated by gradient core assembly 280, an MRI scanner can be configured so that one or more or shim drawers 32 and bore 502 are electrically connected. In one embodiment, MRI scanner 100 can have a conductive member 602 in a ring configuration for electrically connecting a plurality of shim drawers 32 to bore 502 at first locations “I” and a member 604 in a ring configuration for electrically connecting a plurality of shim drawers 32 to bore 502 at second locations spaced apart from the first locations “II”.

It is to be understood that the above description is intended to be illustrative, and not restrictive. For example, the above-described embodiments (and/or aspects thereof) may be used in combination with each other. In addition, many modifications may be made to adapt a particular situation or material to the teachings of the various embodiments without departing from their scope. While the dimensions and types of materials described herein are intended to define the parameters of the various embodiments, they are by no means limiting and are merely exemplary. Many other embodiments will be apparent to those of skill in the art upon reviewing the above description. The scope of the various embodiments should, therefore, be determined with reference to the appended claims, along with the full scope of equivalents to which such claims are entitled. Forms of the term “defined in the appended claims, the terms “including” and “in which” are used as the plain-English equivalents of the respective terms “comprising” and “wherein.” Moreover, in the following claims, the terms “first,” “second,” and “third,” etc. are used merely as labels, and are not intended to impose numerical requirements on their objects. Further, the limitations of the following claims are not written in means-plus-function format and are not intended to be interpreted based on 35 U.S.C. §112, sixth paragraph, unless and until such claim limitations expressly use the phrase “means for” followed by a statement of function void of further structure. It is to be understood that not necessarily all such objects or advantages described above may be achieved in accordance with any particular embodiment. Thus, for example, those skilled in the art will recognize that the systems and techniques described herein may be embodied or carried out in a manner that achieves or optimizes one advantage or group of advantages as taught herein without necessarily achieving other objects or advantages as may be taught or suggested herein.

While the invention has been described in detail in connection with only a limited number of embodiments, it should be readily understood that the invention is not limited to such disclosed embodiments. Rather, the invention can be modified to incorporate any number of variations, alterations, substitutions or equivalent arrangements not heretofore described, but which are commensurate with the spirit and scope of the invention. Additionally, while various embodiments of the invention have been described, it is to be understood that aspects of the disclosure may include only some of the described embodiments. Accordingly, the invention is not to be seen as limited by the foregoing description, but is only limited by the scope of the appended claims.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal language of the claims.

1. An MRI scanner comprising:
a magnet assembly forming a central magnetic field area;
a slot for receiving a shim drawer, the slot formed within the central magnetic field area;
a shim drawer received in the slot, wherein the shim drawer is configured to carry one or more metal shim, wherein the shim drawer includes conductive material.

2. The MRI scanner of claim 1, wherein the shim drawer is formed of aluminum.

3. The MRI scanner of claim 1, wherein the shim drawer includes an insulator coating for reducing or preventing metal to metal contact between the shim drawer and the one or more conductive shim.

4. The MRI scanner of claim 1, wherein the MRI scanner includes one or more conductive shims carried by the conductive shim drawer, the one or more conductive shim is formed of iron.

5. The MRI scanner of claim 1, wherein the one or more conductive shim includes an insulator coating for reducing or preventing metal to metal contact between the shim drawer and the one or more conductive shim.

6. The MRI scanner of claim 1, including the shim drawer and a second shim drawer, the second shim drawer including conductive material, wherein the MRI scanner is configured so that the shim drawer and the second shim drawer are electrically connected.

7. The MRI scanner of claim 1, including the shim drawer and a second shim drawer, the second shim drawer including conductive material, wherein the MRI scanner is configured so that the shim drawer and the second shim drawer are electrically connected at first and second spaced apart locations to define a closed conductive current path between the shim drawer and the second shim drawer.

8. The MRI scanner of claim 1, including the shim drawer and second third and fourth shim drawers, each of the second third and fourth shim drawers including conductive material, wherein the MRI scanner includes a conductive member having a ring configuration, wherein the MRI scanner is configured so that each of the shim drawer, second, third and fourth shim drawers electrically contacts the conductive member when fully installed into the MRI scanner.

9. The MRI scanner of claim 1, including the shim drawer and second third and fourth shim drawers, each of the second third and fourth shim drawers including conductive material, wherein the MRI scanner includes a conductive member having a ring configuration, wherein the MRI scanner is configured so that each of the shim drawer, second, third and fourth shim drawers electrically contacts the conductive member when fully installed into the MRI scanner, wherein the MRI scanner includes a second conductive member, the second conductive member being removeably received in the MRI scanner and having a ring configuration, the conductive member providing electrical connection between the shim assembly, the second third, and fourth shim assembly at first locations, the second conductive member providing electrical connection between the shim assembly, the second third, and fourth shim assembly second locations spaced apart from the first locations.

10. The MRI scanner of claim 1, wherein the MRI scanner includes a gradient coil assembly disposed within the central magnetic field area, and a conductive bore having a cylindrical configuration, the conductive bore defining the slot and being disposed between the gradient coil assembly and the magnet assembly, wherein one or more the conductive bore and the shim drawer includes an insulator coating for reducing or preventing conductive material to conductive material contact between the conductive bore and the shim drawer.

11. A shim drawer assembly comprising:
a shim drawer;
wherein the shim drawer is configured to carry one or more metal shim;
one or more metal shim disposed in the shim drawer;
wherein the shim drawer is formed of conductive material,

12. The shim drawer assembly of claim 11, wherein the shim drawer is formed of aluminum.

13. The shim drawer assembly of claim 11, wherein the shim drawer includes an insulator coating for reducing or preventing metal to metal contact between the shim drawer and the one or more conductive shim.

14. The shim drawer of claim 11, wherein the one or more conductive shim is formed of iron.

15. The shim drawer assembly of claim 11, wherein the one or more conductive shim includes an insulator for reducing or preventing metal to metal contact between the shim drawer and the one or more conductive shim.

16. The shim drawer assembly of claim 11, wherein a bottom surface of the shim drawer includes an insulator coating for reducing or preventing conductive material to conductive material contact between the shim drawer and a slot for supporting the shim drawer.
